(19) United States
(12) Patent Application Publication
(10) Pub. No.: US 2025/0189886 A1
(43) Pub. Date: Jun. 12, 2025

(54) ORGANOTIN POLYMER PHOTORESIST COMPOSITION FOR PHOTOLITHOGRAPHY PATTERNING

(71) Applicant: Feng Lu, Irvine, CA (US)

(72) Inventor: Feng Lu, Irvine, CA (US)

(21) Appl. No.: 18/963,997

(22) Filed: Nov. 29, 2024

Related U.S. Application Data
(60) Provisional application No. 63/607,241, filed on Dec. 7, 2023.

(51) Int. Cl. G03F 7/004

(52) U.S. Cl. CPC G03F 7/0042

(57) ABSTRACT

An organotin polymer photoresist composition for photolithography patterning is described, wherein organotin polymer photoresist composition comprises an organotin polymer, a solvent, and/or an additive. Organotin polymer comprises cyclopentadienyl group, wherein cyclopentadienyl comprises cyclopentadienyl C₅H₅ group, or substituted cyclopentadienyl C₅H₃R, C₅H₂R₂, C₅HR₃, C₅R₄, or C₅R₅ group, wherein R is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group.

### CROSS REFERENCE TO RELATED APPLICATIONS

This application claims priority to U.S. provisional patent application No. 63/607,241 filed on Dec. 7, 2023 to Lu, entitled “Organotin polymer photoresist composition for photolithography patterning”, of which is entirely incorporated herein by reference.

### FIELD OF INVENTION

The present invention relates to organotin polymer photoresist composition for photolithography patterning, wherein organotin polymer photoresist composition comprises an organotin polymer, a solvent, and/or an additive. Organotin polymer comprises cyclopentadienyl group, or substituted cyclopentadienyl group.

### BACKGROUND

With the development of the semiconductor industry, nanoscale patterns have been in pursuit of higher devices density, higher performance, and lower cost. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light absorption because metals have high absorption capacity of ultraviolet radiation with various carbon-metal (C-M) bond dissociation energy (BDE), and then can be used as photoresists and/or precursors for photolithography at smaller level (e.g., <7 nm), which is of great interests for radiation lithography. Among those promising advanced materials, particularly organometallic tin (organotin) compounds can provide photoresist patterning with significant advantages, such as improved resolution, sensitivity, etch resistance, and lower line width/edge roughness without pattern collapse because of strong EUV radiation absorption of tin, which have been demonstrated.

### SUMMARY

In a first aspect, the present invention pertains to organotin polymer photoresist composition for photolithography patterning, particularly for extreme ultraviolet radiation (EUV). The organotin polymer photoresist composition comprises an organotin polymer, a solvent, and/or an additive. The additive is organic molecule, including organic thiol, organic alcohol, organic amine, organic amide, organic carboxylic acid, organic phosphine, organic phosphine oxide, or organic phosphonic acid. The present invention is to provide improved resolution sensitivity, etch resistance, and lower line width/edge roughness without pattern collapse for photolithography patterning.

In another aspect, the invention pertains to radiation sensitive organotin polymer photoresist, having a chemical structure containing cyclopentadienyl group selected from the following:

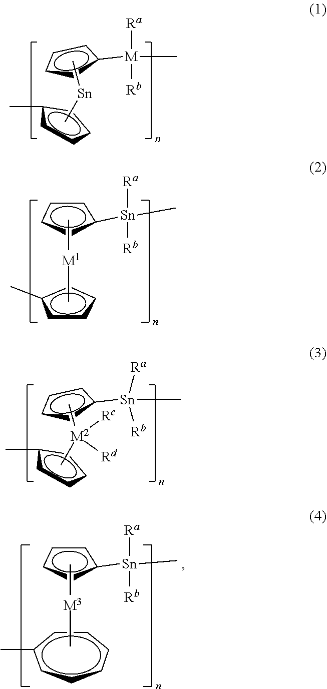

wherein M=C, Si, Ge, Sn, or Pb; M¹=Fe, Ru, Ni, V, Co, Zn, Mg, Cr, Mn, Sb, Bi, or In; M²=Sn, Ti, Zr, Hf, or Nb; M³=Ti, V, or Cr; R^{a}, R^{b}, R^{c}, R^{d} are each independently —R¹, —ER¹, —N(R¹)₂, or —O—(C═O)R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te. In some embodiments, the precursors for the preparation of organotin polymers (1)-(4) as above described, may be represented by corresponding chemical formula containing cyclopentadienyl group as the following:

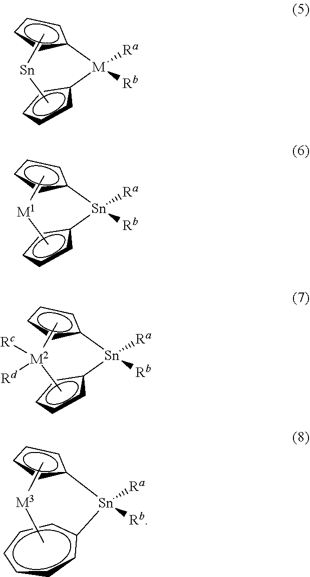

Wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group.

In a further aspect, in the present disclosure, organotin polymer may be synthesized through ring-opening polymerization (ROP) method of ansa-bridge [1] metallocenophanes (5)-(8) under ambient conditions. ROP method comprises thermal-initiated ROP in the solid state and in solution, or photo-initiated ROP in solution, in the presence/absence of the Karstedt catalyst. For example, in one exemplary embodiment, one organotin polymer represented by (stannocenyl) tin polymer (1) can be prepared through the polymerization of ansa-bridge [1] stannocenophanes (5) under ambient conditions depicted as below:

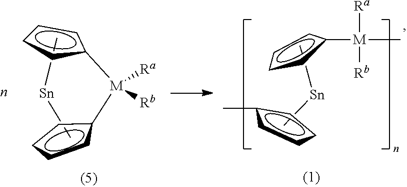

wherein M=C, Si, Ge, Sn, or Pb; R^{a}, R^{b} are each independently —R¹, —ER¹, —N(R¹)₂, or —O—(C═O)R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te. According to the similar manner, organotin polymer (2), (3), and (4) can be prepared under ambient conditions, including but not limited to. In some embodiments, in situ thermal- or photo-initiated ring-opening polymerization of precursors (5)-(8) may be performed over a surface of semiconductor substrate for photolithography patterning.

Stannocenyl comprises cyclopentadienyl C₅H₅ group, or substituted cyclopentadienyl C₅H₄R, C₅H₃R₂, C₅H₂R₃, CHR₄, or C₅R₅ group with hapticity of η¹, η², η³, η⁴, or η⁵ of isomers, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

In other aspects, the present invention pertains to a method of stabilization; wherein an organic additive stabilizes organotin polymer photoresist composition for photolithography patterning. Organic additive stabilization may overcome the disadvantages like poor stability and solubility and/or short shelf time from non-stabilized conventional organotin photoresists. The method of stabilization comprises the addition of organic additive to stabilize the as-formed organotin polymer photoresist, and to prevent from aggregation occurred or precipitate formation. The aggregation and precipitation can lead to scums or defects on the surface of substrates during photolithography patterning. The organic additives contain various functional groups, such as —SH, —OH, —NH₂, —COOH, —CONH₂.

The photosensitivity, thermostability and uniformity of organotin polymer photoresist compositions determine high resolution and efficiency of photolithography.

In an additional aspect, the invention relates to radiation sensitive organotin polymer photoresist composition, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line width roughness, high resolution, low dose and large contrast, such as for <7 nm.

### BRIEF DESCRIPTION OF THE DRAWINGS

FIG. 1 illustrates a flowchart of organotin polymer photoresist radiation photolithography patterning processing over a surface of semiconductor substrate.

### DETAILED DESCRIPTION

The present invention pertains to organotin polymer photoresist composition for photolithography patterning, particularly for extreme ultraviolet radiation (EUV), wherein organotin polymer photoresist composition comprises an organotin polymer, a solvent, and/or an additive. The organotin polymer contains cyclopentadienyl group, wherein cyclopentadienyl comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers. For example, organotin polymer contains stannocenyl group, which comprises bis(cyclopentadienyl) tin, or substituted bis(cyclopentadienyl) tin. The present invention is to provide a method of photolithography patterning of organotin polymer photoresist composition, particularly, suitable for EUV lithography (e.g. <7 nm). The method of photolithography patterning comprises depositing an organotin polymer photoresist composition over a substrate to form a photoresist layer after baking; exposing the photoresist layer to actinic radiation to form a latent pattern; and developing the latent pattern by applying a developer to remove unexposed or exposed portion of photoresists to form a photolithography pattern. In some embodiments, organometallic precursors containing cyclopentadienyl represented by chemical formulas (5)-(8) may be deposited over a surface of substrate for in situ thermal- or photo-initiated ring-opening polymerization to form corresponding organotin polymer (1)-(4) layer, and then for photolithography patterning. The present invention is further to provide a method of stabilization of organotin polymer photoresist by applying organic molecules as additives to stabilize organotin polymer. Organic molecules-stabilized organotin polymer photoresists may have higher resolution, sensitivity, solubility, stability, shelf life, and lower width roughness without pattern collapse during microelectronic patterning compared with conventional organic polymer photoresist or inorganic photoresist. The photosensitivity and thermostability of organotin polymer photoresists determine high resolution and efficiency for photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The terms “alkyl” or “alkyl group” refers to a saturated linear or branched-chain hydrocarbon of 1 to 20 carbon atoms. The terms “alkenyl, alkynyl” refers to hydrocarbon of 2 to 20 carbon atoms. The terms “cycloalkyl, cycloalkenyl” refers to hydrocarbon of 3 to 20 carbon atoms. The term “aryl” refers to unsubstituted or substituted aromatic group with 6-20 carbon atoms. The substituted group includes, but not limited to, amide, amine, cyano, ether, cyclic ether, ester, cyclic ester, halide, imine, nitro, silyl, thiol, or carbonyl group. The term “alkylene” refers to a saturated divalent hydrocarbon by removal of two hydrogen atoms from a saturated hydrocarbon of 1 to 20 carbon atoms, e.g., methylene (—CH₂—), ethylene (—CH₂CH₂—), or the like.

The term “amine” refers to primary (—NH₂), secondary (—NHR), tertiary (—NR₂) amine group. The term “cyclic amine” refers to [R—NH—R′], wherein [R—R′] is cyclic substituted and unsubstituted C₃ to C₈ organic group, including, but not limited to:

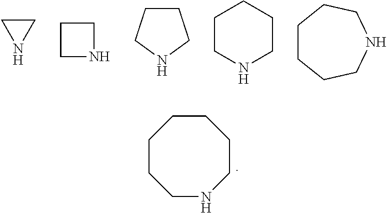

The term “ether” refers to the R—O—R′ group. The term “cyclic ether” refers to the [R—O—R′], wherein [R—R′] is cyclic substituted and unsubstituted C3 to C8 organic group, including, but not limited to:

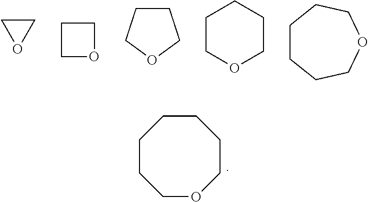

The term “ester” refers to the R—(C═O)—O—R′ group. The term “cyclic ester” refers to the [R—(C═O)—O—R′], wherein [R—R′] is cyclic substituted and unsubstituted C4 to C8 organic group, including, but not limited to:

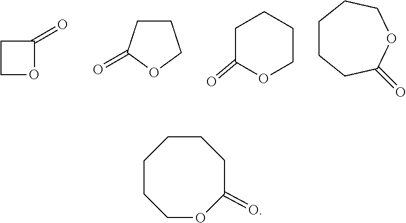

The term “halide” refers to the fluorine (F), chlorine (Cl), bromine (Br), or iodine (I). The term “nitro” refers to the —NO₂. The term “silyl” refers to the —SiR—, —SiR₂—, or —SiR₃ group. The term “thiol” refers to —SH group. The term “carbonyl” refers to the —C═O group. The term “oxo” refers to —O—, or ═O.

In the present disclosure, the term “substituted” refers to replacement of a hydrogen atom with a C1 to C20 alkyl group, a C2 to C20 alkene group, a C2 to C20 alkyne group, a C3 to C20 cycloalkyl group, a C6 to C20 aryl group, or other relevant groups including, but not limited to amide, amine, cyclic amine, cyano, ether, cyclic ether, ester, cyclic ester, halide, imine, nitro, silyl, thiol, or carbonyl group.

The terms “η¹” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom. The terms “′η⁵” refers to five carbon atoms bonded to one metal atom. For example, η¹, η⁵ are correspondingly depicted as following (M=metal):

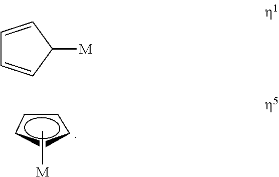

EUV lithography is under the development for the mass production of next generation <7 nm node. EUV photoresists are required to achieve higher performance, higher sensitivity and resolution, and cost reduction.

EUV light has been applied for photolithography at about 13.5 nm. The EUV light can be generated from Sn plasma or Xe plasma source excited using high energy lasers or discharge pulses.

For conventional organic polymer photoresists, if the aspect ratio, which is the height divided by width, is too large that would lead to pattern structures susceptible to collapse, and also associated with surface tension, which would limit the application for smaller features like <7 nm.

For small feature sizes like <7 nm, such as 1-3 nm, the conventional chemically amplified (CA) organic polymer photoresists encounter critical issues, such as poor EUV light absorption, low resolution, high line edge roughness (LER), increased pattern collapses and defects. In order to overcome the disadvantages from conventional organic polymer photoresists or inorganic photoresists, novel organometallic photoresists, or organometallic photosensitive compositions, particularly for EUV, have been called for.

Organometallic photoresists are used in EUV lithography because metals have high absorption capacity of EUV radiation. Radiation sensitivity and thermal-, oxygen- and moisture-stability are important for organometallic photoresists. In some embodiments, organometallic photoresists may absorb moisture and oxygen, which may result in decreasing stability, as well decreasing solubility in developer solutions. In addition, in some embodiments, photoresist layer may outgas volatile components prior to the radiation exposure and development operations, which may negatively affect the lithography performance, pattern collapse and increase defects.

In general, metal central plays the key role in determining the absorption of photo radiation. Meanwhile for organometallic compounds, the metal-bonded organic ligands (M-R, M =metal, R=cleavable/hydrolysable organic ligands) may also influence the relevant absorption through M-C bonding. Therefore, tuning and modification of organic ligands can change the resolution, sensitivity and radiation absorption, and the desired control of the material properties.

Tin atom provides strong absorption of extreme ultraviolet (EUV) light at 13.5 nm, therein tin cations can be selected based on the desired radiation and absorption cross section. Meanwhile, organic ligand bonded to tin also has absorption of EUV light.

The bond dissociation energy (BDE) of Sn—C bond determines the light absorption wavelength, corresponding smaller features, and patterned structures.

Organotin photoresists have excellent (e.g., suitable) sensitivity to high energy light (e.g., EUV, DUV, X-ray, or laser) due to tin strong absorption of extreme ultraviolet (EUV) at about 13.5 nm. Accordingly, organotin photoresists have improved sensitivity, resolution, stability compared with conventional organic polymer or inorganic photoresists.

In some embodiments, organotin photoresist comprises small organometallic tin compound, or organotin cluster with large molecular weight. In some embodiments, the small organometallic tin compound contains one, two, or three tin atoms. In some embodiments, organotin cluster contains more than three tin atoms, for example, twelve. In some embodiments, organotin photoresist comprises organotin polymer, for example, poly (stannocenyl) tin.

The organotin photoresists comprise organic ligand, Sn—C bond, Sn—O bond, or Sn—O—Sn bond providing desirable radiation sensitive and stabilization for photolithography patterning. The organotin photoresists possess excellent properties for photolithographic patterning.

Organotin polymer photoresist composition according to embodiments of the present disclosure may have improved etch resistance, sensitivity and resolution, compared with conventional organic polymer or inorganic resists.

Examples of specific organotin polymer photoresists may be used in implementations of the invention, having a chemical structure bearing cyclopentadienyl selected from the following:

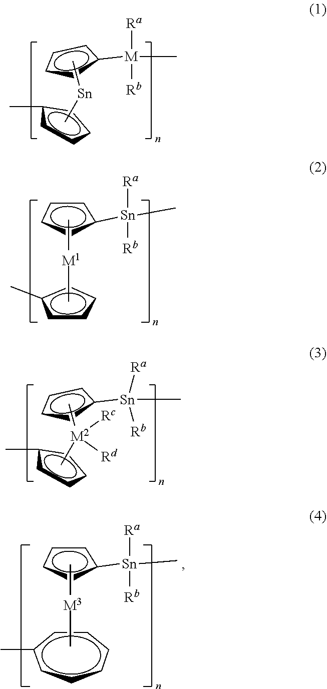

wherein M=C, Si, Ge, Sn, or Pb; M¹=Fe, Ru, Ni, V, Co, Zn, Mg, Cr, Mn, Sb, Bi, or In; M²=Sn, Ti, Zr, Hf, or Nb; M³=Ti, V, or Cr; R^{a}, R^{b}, R^{c}, R^{d} are each independently —R¹, —ER¹, —N(R¹)₂, or —O—(C═O)R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te.

Wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, an alkyl, alkenyl, alkynyl, or cycloalkyl group with 1 to 20 carbon atoms, or an aryl group with 6-20 carbon atoms, or an amino, cyano, ether, ester, halide, nitro, silyl, thiol, or carbonyl group.

In some embodiments, organotin polymers represented by chemical formulas (1)-(4) may be synthesized through ring-opening polymerization (ROP) of ansa-bridge [1] metallocenophanes under ambient conditions. Herein ROP comprises thermal-initiated ROP, or photo-initiated ROP in the solid state and in solution, in the presence/absence of the Karstedt catalyst.

In some embodiments, organometallic photoresist precursors of ansa-bridge [1] metallocenophanes for the preparation of above-described organotin polymers (1)-(4) comprise corresponding chemical formulas (5)-(8) bearing cyclopentadienyl group depicted as below:

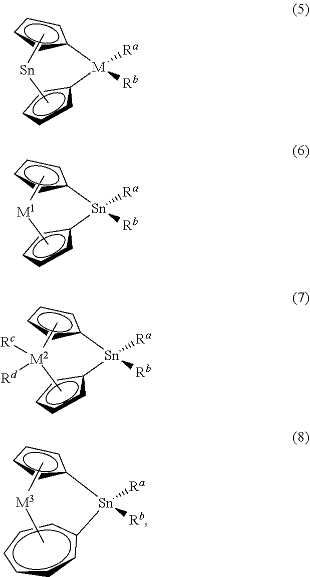

wherein M=C, Si, Ge, Sn, or Pb; M¹=Fe, Ru, Ni, V, Co, Zn, Mg, Cr, Mn, Sb, Bi, or In; M²=Sn, Ti, Zr, Hf, or Nb; M³=Ti, V, or Cr; R^{a}, R^{b}, R^{c}, R^{d} are each independently-R¹, —ER¹, —N(R¹)₂, or —O—(C═O)R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te.

In some embodiments, organometallic ansa-bridge [1] metallocenophanes containing cyclopentadienyl represented by chemical formulas (5)-(8) may be deposited over a surface of substrate for in situ photo-initiated or thermal-initiated ring-opening polymerization to form organotin polymer, and then for photolithography patterning. In some embodiments, organometallic ansa-bridge [1] metallocenophanes also may be used as photoresists.

In some embodiments, organotin polymer (1) comprises stannocenyl group, wherein stannocenyl comprises bis(cyclopentadienyl) tin, or substituted bis(cyclopentadienyl) tin.

In some embodiments, cycloalkenyl group comprises substituted and unsubstituted C₄ to C₈ aliphatic unsaturated organic groups including at least one double bond, for example,

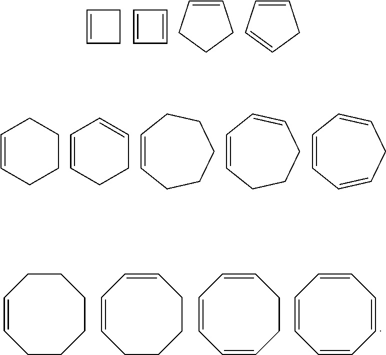

For example, in some embodiments, M=Sn.

For example, in some embodiments, R¹ is H, an alkyl, alkenyl, alkynyl, cycloalkyl, cycloalkenyl, or aryl group, such as, methyl (Me), ethyl (Et), isopropyl (i-Pr), n-butyl (n-Bu), t-butyl (t-Bu), t-amyl, s-butyl, pentyl, hexyl, neopentyl (Neo), cyclohexyl, cyclopentyl, cyclobutyl, cyclopropyl, cyclopentadienyl, phenyl (Ph), or benzyl (Ben) group.

For example, in some embodiments, R^{a}, R^{b}, R^{c}, R^{d} are each independently alkoxide group, such as —OMe, —OEt, —OPr, —Oⁿ⁻Bu, —O^{t-}Bu, —OPh, or OBen group.

For example, in some embodiments, R^{a}, R^{b}, R^{c}, R^{d} are each independently amine group, such as —NMe₂, —NEt₂, —NPr₂, —N(ⁿ⁻Bu)₂, —N(^{t-}Bu) 2, or —NPh₂ group.

For example, in some embodiments, R^{a}, R^{b}, R^{c}, R^{d} are each independently ester group, such as —O—(C═O) Me, —O—(C═O) Et, —O—(C═O)Pr, —O—(C═O)ⁿ⁻Bu, —O—(C═O)^{t-}Bu, or —O—(C═O)Ph.

In the present disclosed patent, organotin polymer photoresists comprise cyclopentadienyl group, Sn—C bond, or Sn—O bond, or Sn—S bond, or Sn—Se bond, or Sn—Te bond, or Sn—N bond providing desirable radiation sensitive and stabilization for precursor metal cations. Therefore, organotin polymer photoresists possess excellent properties for photolithographic patterning.

As one of ordinary skill in the art will recognize, the organotin polymers listed here are merely intended as illustrated examples of organotin polymer photoresists, and are not intended to limit the embodiments to only those organotin polymer photoresists specifically described. Rather, any suitable organotin polymer photoresist may be used, and all such organotin polymer photoresists are fully intended to be included within the scope of the present embodiments.

In one exemplary embodiment, as for the preparation of (stannocenyl) tin polymer (1), stannocene (η⁵-C₅H₅)₂Sn (Sc) is used as parent molecule for carrying out lithiation at one or two C₅ rings, such as mono-lithiation, or bi-lithiation, by strong bases, for example, methyllithium (MeLi), n-butyllithium (n-BuLi), s-butyllithium (s-BuLi), or t-butyllithium (t-BuLi), and then followed by further procedures to synthesize desired derivatives. For example, in one exemplary embodiment, bi-lithiation at two C₅ rings of stannocene can be carried out by n-BuLi at −78° C. in THF to afford (η⁵-C₅H₄Li)Sn(η⁵-C₅H₄Li) (ScLi₂) depicted as below:

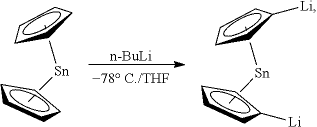

which is according to the references, A. H. Cowley, P. Jutzi, F. X. Kohl, J. G. Lasch, N. C. Norman, E. Schlüter, “Sequential Lithiation and Silylation of Stannocene”, Angew. Chemie International Edition 23 (1984), 8, 616-617; A. H. Cowley, J. G. Lasch, N. C. Norman, C. A. Stewart, and T. C. Wright, “Lithiation and Derivatization of Group 4A Bent-Sandwich Molecules”, Organometallics 1983, 2, 1691-1692, all of which are incorporated herein by references. In some embodiments, the addition of coordination reagent is required to improve the yield of bi-lithiation at two C₅ rings, for example, (N,N,N′,N′-tetramethyl-1,2-diaminotheane (TMEDA). A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In the present disclosure, organotin compound ansa-bridged [1] stannocenophane can be used as monomer precursor for the preparation of organotin polymer (stannocenyl) tin polymer (1) under ambient conditions. In an exemplary embodiment, the organotin compound ansa-bridged [1] stannocenophanes can be prepared according to the following method:

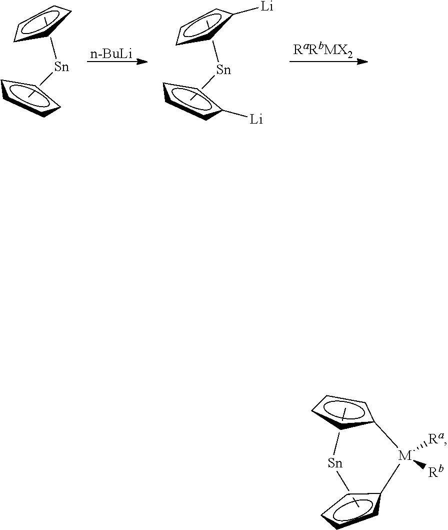

wherein M=C, Si, Ge, Sn, or Pb; R^{a}, R^{b} are each independently —R¹, —ER¹, —N(R¹)₂, or —O—(C═O) R¹, wherein R¹ is H, a substituted or unsubstituted alkyl, alkenyl, alkynyl, cycloalkyl, or cycloalkenyl group with 1 to 20 carbon atoms, or a substituted and unsubstituted aryl group with 6-20 carbon atoms; E=O, S, Se, or Te; X=F, Cl, Br, or I. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In another exemplary embodiment, the organotin ansa-bridged [1] stannocenophanes may be prepared according to the following method:

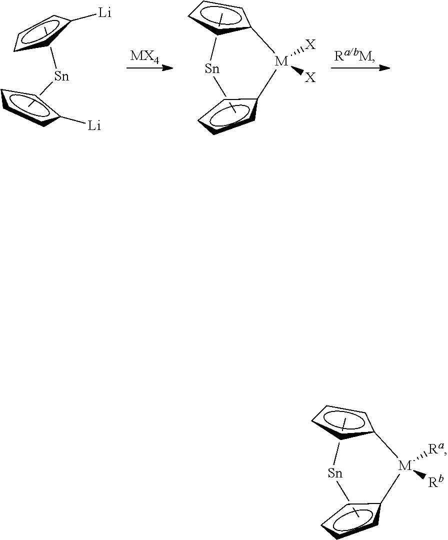

wherein M=C, Si, Ge, Sn, or Pb; R^{a/b}M′ includes, but not limited to, R^{a/b}M′ (M′=Li, Na, or K), Grignard reagents R^{a/b}MgCl, or R^{a/b}₂CuLi. R^{a}, R^{b} are each independently-R¹, —ER¹, —N(R¹)₂, or —O—(C═O) R¹, wherein R¹ is a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; X=F, Cl, Br, or I; E=O, S, Se, or Te. For example, n-BuLi, ^{t}BuLi, ^{t}BuMgCl, ^{t}BuOK, ^{t}Bu₂NLi, or CH₃COONa. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In further exemplar embodiment, the organotin ansa-bridged [1] stannocenophanes may be prepared according to the following method:

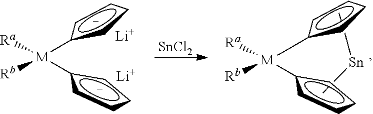

wherein M=C, Si, Ge, Sn, or Pb. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

For example, in one exemplary embodiment, (stannocenyl) tin polymer was prepared by the ring-opening polymerization (ROP) of respective monomer ansa-bridged [1] stannocenophanes under ambient conditions shown as below:

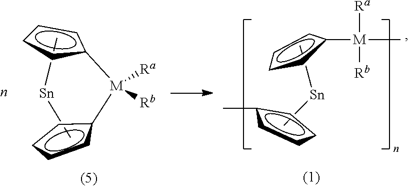

wherein M=C, Si, Ge, Sn, or Pb, for example, silicon-bridged [1] stannocenophanes, tin-bridged [1] stannocenophanes (stanna [1] stannocenophanes). The ROP method comprises thermal-initiated ROP in the solid state, or ROP in solution, or photo-initiated ROP in solid or solution under ambient temperature, which may result in different molecular weight polymer, such as high-molecular-weight polymer or low-molecular-weight polymer. A person of ordinary skills in the art will recognize that the synthetic strategies, reagents, solvents, or reaction conditions including reactant ratios, temperature, reaction time, or addition manner within the explicit ranges of above are contemplated and are within the present disclosure.

In one example embodiment, the ROP was carried out in the solid state at high temperature (e.g., 20-300° C.), for example the solid stanna [1] stannocenophane was polymerized at 200° C.

In another exemplary embodiment, the ROP was performed in solution, for example, the monomer ansa-bridged [1] stannocenophane in organic solvent at ambient temperature (e.g., —196-300° C.). The organic solvent includes, but not limited to hexane, diethyl ether, ethanol, methanol, THF, methylene chloride, chloroform, benzene, toluene, or xylene. For example, the solid monomer ansa-bridged [1] stannocenophane was polymerized in chloroform at 30° C.

The molecular weight (Mw or Mn) of as-formed organotin polymer depends on the reaction condition and method, such as in the solid state or in solution, as high molecular weight or low molecular weight. The solvent also plays a key role in determining the molecular weight. The molecular weight can be identified by gel permeation chromatography (GPC). The exact molecular weight may vary from different experiments or reaction conditions with a range.

The invention pertains to methods for preparation and purification of organometallic precursors and polymers. All chemical manipulations, including preparation and purification, are performed under an inert atmosphere of purified nitrogen or argon in dry and degassed solvents by employing standard Schlenk techniques. The methods for purification comprise distillation, extraction, filtration, recrystallization, column chromatography, coordination, sublimation, vaporization, and combinations thereof. In some embodiments, recrystallization may result in single crystals, which are suitable for X-ray diffraction analysis for determining molecular structures.

The organotin polymer contains Sn—C, or Sn—N, or Sn—O, or Sn—S, or Sn—Se, or Sn—Te bond with different bond dissociation energy (BDE) and sensitivity to extreme ultraviolet light.

Organotin photoresist bearing unsaturated cycloalkenyl group and Ccycloalkenyl-Sn bond, such as cyclopentadienyl or substituted-cyclopentadienyl group, according to embodiments of the present disclosure, may have improved etch resistance, sensitivity, and resolution.

The organotin polymers contain cyclopentadienyl C₅H₅, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6-20 carbon atoms. For example, R is methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

Cyclopentadienyl group (C₅R₅, or Cp) may impart photosensitivity to the compounds. The formed Cₚ-Sn bond may promote suitable solubility in organic solvent to cyclopentadienyl-containing organotin compound photoresist. Accordingly, Cₚ-Sn bond containing organotin compound photoresist, according to an embodiment, may have improved sensitivity, resolution, etch resistance, and stability, and may suitable for EUV photoresists, and/or as precursors for EUV lithography to form tin oxide or tin oxide hydroxide film.

The present organotin polymers contain cyclopentadienyl-Sn bond (Cₚ-Sn bond). Cₚ-Sn bond is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis (cyclopentadieny 1) tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅· radical. This study demonstrated cyclopentadienyl (C₅H₅) group or substituted cyclopentadienyl (C₅R₅) group has higher UV light sensitivity compared with alkyl (e.g., methyl, butyl) group under identical condition. This property is beneficial to decrease EUV light dose and increase resolution.

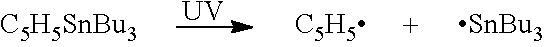

The organotin polymers contain tin and C—Sn bond, therefore may absorb extreme ultraviolet light at 13.5 nm.

Organotin polymer photoresists contain cyclopentadienyl (Cₚ), or substituted-cyclopentadienyl group, x bond, C—Sn bond and related interaction and may have excellent (e.g., suitable) sensitivity to high energy light (e.g., EUV, or DUV) due to tin absorption high energy EUV ray at 13.5 nm. Accordingly, organotin polymer photoresist may have improved sensitivity, resolution, and stability compared with conventional organic polymer photoresist or inorganic photoresist.

Organotin polymer photoresists may have excellent sensitivity to EUV radiation light due to the tin absorption high energy EUV ray at 13.5 nm (low expose dose photoresist, e.g., <20 mJ/cm²), and the disruption of Cₚ-Sn bond to form free radical, tin oxide and relative products, and toughness; low or free pattern defectivity at nanoscale. Accordingly, the solution composition of organotin polymer photoresists may have tight pitch (e.g., <10 nm), and may sustain the yield and deliver high resolution.

Organotin monomers or polymers containing cyclopentadienyl group may have hapticity of η¹, η², η³, η⁴, or η⁵ of isomers.

The organotin polymer photoresist composition may include 0.1 wt % to 30 wt % of organotin polymer, based on the total weight of the organotin polymer photoresist composition. A person of ordinary skills in the art will recognize that the samples, concentrations, and amounts of organotin polymer within the explicit ranges of above are contemplated and are within the present disclosure.

In some embodiments, organotin polymer photoresists or organometallic photoresist precursor ansa-bridge [1] metallocenophanes are soluble in appropriate organic solvents with improved uniformity for photolithography pattern processing. The solution compositions can be formed by dissolving in organic solvents, including but not limit to, pentane, hexane, cyclohexane, methylene chloride, chloroform, tetrahydrofuran (THF), dimethoxyethane (DME), dimethylformamide (DMF), dimethyl sulfoxide (DMSO), alcohols (e.g., 4-methyl-2-pentenol, methanol, ethanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of organotin polymer can be utilized as EUV photoresist composition for further processing and patterning. A person of ordinary skills in the art will recognize that the choice of solvents and solution composition components within the explicit ranges of above are contemplated and are within the present disclosure.

In general, the poor stability of organotin or organotin cluster photoresists in solution after aged would lead to aggregation or precipitation with short shelf life for photolithography, which then would result in scums or defects in photolithography patterning. In some embodiments, the addition of organic additive may increase the stability of the radiation sensitive organotin polymer photoresist composition.

In some embodiments, the hydrolysable or cleavable ligands of organotin compound, cluster, or polymer photoresist precursors carry out hydrolysis with water or moisture from promoting agent to form free hydroxyl (—OH) groups, and then condensation to form organotin clusters. For example, in some embodiments, in situ hydrolysis of organometallic precursors form organometallic dimer represented by (RₙM)₂(OH)₂L₄₋ₙ(H₂O)₂ (M=metal, R=organic ligand). The aggregation of organotin clusters or polymers in the presence of organometallic dimer bearing free-OH groups is prevented due to the complete hydrolysis of organometallic dimer. The aggregation of organotin clusters or polymers would bridge over proximate resist patterns and then lead to scum.

In some embodiments, the stability of organotin polymer photoresists in solution can be improved by organic molecules as stabilizers. The organic molecules-stabilized organotin polymer photoresists possess improved solubility, uniformity, or shelf life for photolithography patterning.

In some embodiments, organic molecule stabilizers include, but not limited to, organic thiol, organic alcohol, organic amine, organic amide, organic carboxylic acid, organic phosphine, phosphine oxide, or organic phosphonic acid, or a combination thereof.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or a combination thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or a combination thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or a combination thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or a combination thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or a combination thereof.

In some embodiments, organic phosphine, phosphine oxide, or phosphonic acid, include, but not limited to, trioctylphosphine, tributylphosphine, tris (dimethylamino) phosphine, tris (diethylamino) phosphine, trioctylphospine oxide, hexylphosphonic acid, octadecylphosphonic acid, 11-undecenyl phosphonic acid, or a combination thereof.

In some embodiments, organotin polymer photoresists may comprise functional groups, including but not limited to, amine, amide, cyano, carbonyl, carboxylic acid, ether, halogen, hydroxy, keto, thiol, silyl, or combinations thereof.

In some embodiments, organic molecules additive stabilizers may be adsorbed, grafted, immobilized, anchored, or coordinated on organotin polymer photoresists as supports.

In some embodiments, the organic molecules stabilized organotin polymer photoresist composition according to an embodiment is prepared by the addition of organic molecular stabilizer to the solution of organotin polymer under ambient condition. A person of ordinary skills in the art will recognize that the temperatures and addition within the explicit ranges of above are contemplated and are within the present disclosure.

The solution composition of organotin polymer photoresist can be utilized for photolithography patterning including extreme ultraviolet radiation (EUV) (13.5 nm), deep ultraviolet radiation (DUV) such as KrF excimer laser (248 nm) or ArF excimer laser (193 nm), e-beam radiation, X-ray radiation, or ion-beam radiation for further processing and patterning.

The present invention encompasses organotin polymer photoresist composition for photolithography patterning. The photolithography patterning comprises forming an organotin polymer photoresist composition; wherein the forming the organotin photoresist composition comprises an organotin polymer, a solvent, and/or an additive; organotin polymer photoresist may be stabilized by organic molecules as additives. The formed organotin polymer photoresist composition is then deposited over a substrate such as silicon, silicon oxide to form photoresist layer. After baking at appropriate temperature, the organotin polymer photoresist layer is exposed to actinic radiation to form a latent pattern. The formed latent pattern is developed by applying a developer to remove unexposed or exposed portion of photoresists to form a photolithography pattern.

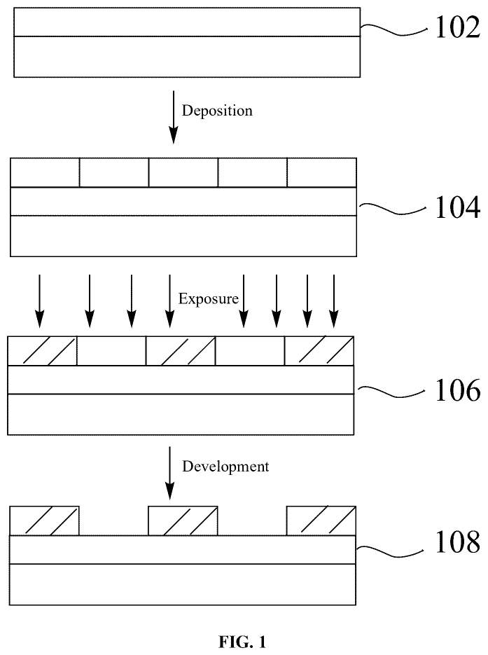

In the present disclosure, a method of forming photolithography pattern using the organotin polymer photoresist composition is illustrated by FIG. 1. The general photolithography process described by FIG. 1, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

In an embodiment, organotin polymer photoresist or organometallic photoresist precursor is deposited on a surface of semiconductor substrate by wet deposition like spin-on coating, spray coating, dip coating, vapor deposition, knife edge coating. In another embodiment, organotin polymer photoresist or organometallic photoresist precursor is deposited by chemical vapor deposition (CVD), atomic layer deposition (ALD), or physical vapor deposition.

In some embodiments, after exposure, the exposed and unexposed portion of organotin polymer photoresists or organometallic photoresist precursors possess different components or chemical and physical properties. Organic ligands of photoresists may be cleaved to form metal oxide or polynuclear oxo/hydroxo network patterns. The unexposed or exposed portions of organotin polymer photoresist or organometallic photoresist precursors may be removed by appropriate wet or dry developer, such as organic solvent or aqueous solution, according to different features, solubility and properties. In some embodiments, the developing method includes sublimation or vaporization under reduced pressure (e.g. in the range of 0.0001 torr to 100 torr) at ambient temperature (e.g. in the range of 20 to 300° C.).

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), methylene chloride, chloroform, aromatic solvents (e.g., benzene, toluene, xylene), acid (e.g., formic acid, acetic acid, oxalic acid, 2-ethylhexanonic acid), and combinations thereof.

In some embodiments, the wet liquid solvent developing process is applied by dipping the exposed/unexposed substrates into a developer bath. In some embodiments, the wet solvent developing solution can be sprayed into the exposed/unexposed photoresists layer.

In some embodiments, the developer is a dry developer including, but not limited to, Cl₂, CH₂Cl₂, BF₃, BCl₃, CF₄, CCl₄, HBr, or combinations thereof.

In some embodiments, the stability, solubility, and uniformity of organotin polymer photoresist composition may be improved, and dissolution during a photolithography such as EUV or DUV. Accordingly, a photolithography pattern having improved performance may be afforded by using of organotin polymer photoresist without scums or defects.

In addition, organotin polymer photoresist compositions for photolithography patterning according to an embodiment is not necessarily limited to negative tone image but may be formed to have a positive tone image.

Organotin polymer photoresists have advantages compared with conventional organic polymer photoresists or inorganic photoresists. However, it will be understood that not all the advantages have been necessarily discussed herein to include all embodiments or examples, other embodiments or examples may offer different advantages.

Hereinafter, the present invention is described in more details through Examples regarding the preparation of organotin monomers or polymers as photoresists for photolithography patterning. However, the present invention is not limited by the Examples. The following examples are provided for further illustration of certain embodiments of the disclosure, which is not necessarily limited to these embodiments.

### EXAMPLES

### Example 1

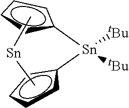

Synthesis of tin-bridged [1] stannocenophane Sn (η⁵-C₅H₄)₂Sn^{t}Bu₂. At −78° C., a solution of ^{t}Bu₂SnCl₂(1.10 mg, 3.66 mmol) in diethyl ether (20 mL) was added dropwise to a solution of [(η⁵-C₅H₄Li]₂Sn (prepared from 1.16 g, 3.66 mmol stannocene, and 5.85 mL/1.6 M, 9.36 mmol n-BuLi) in Et₂O (50 mL) with vigorously stirring. After stirring for hours, the reaction solution was filtered and then the filtrate was evaporated in vacuum to give the titled product. Yield: 1.36 g, 77%. MS (EI): m/z 480 (M⁺).

### Example 2

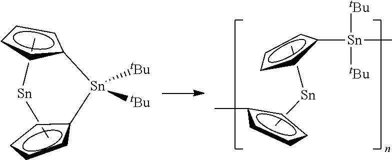

Synthesis of polymer [Sn (η⁵-C₅H₄)₂Sn^{t}Bu₂]ₙ. The polymerization of Sn(η⁵-C₅H₄)₂Sn^{t}Bu₂ was carried out at room temperature in toluene for hours. A solution of Sn (η⁵-C₅H₄)₂Sn^{t}Bu₂ (126 mg, 0.26 mmol) in toluene (10 mL) was stirred at room temperature for 6 hours. The formed polymer [Sn (η⁵-C₅H₄)₂Sn^{t}Bu₂] n was isolated by the addition of hexane as precipitate. The precipitate was filtered and dried in vacuum to give the titled product. Yield: 80%. MS (EI): m/z 426 (Sn(C₅H₅)₂Sn^{t}Bu), 249 (C₅H₅)₂Sn⁺).

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the spirit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin polymer photoresist composition, comprising an organotin polymer, a solvent, and an additive; wherein the organotin polymer having a chemical structure containing cyclopentadienyl group is selected from the following: 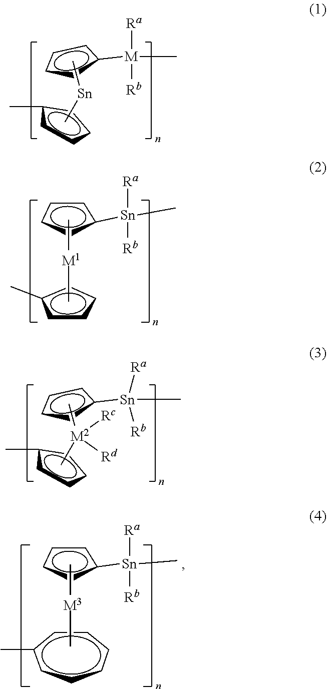
wherein M=C, Si, Ge, Sn, or Pb; M¹=Fe, Ru, Ni, V, Co, Zn, Mg, Cr, Mn, Sb, Bi, or In; M²=Sn, Ti, Zr, Hf, or Nb; M³=Ti, V, or Cr; R^{a}, R^{b}, R^{c}, R^{d} are each independently-R¹, —ER¹, —N(R¹)₂, or —O—(C═O) R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te.

2. The organotin polymer photoresist composition of claim 1, wherein cyclopentadienyl comprises cyclopentadienyl C₅H₅ group, or substituted cyclopentadienyl C₅H₃R, C₅H₂R₂, C₅HR₃, C₅R₄, or C₃R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group.

3. The organotin polymer photoresist composition of claim 2, wherein R is H, a methyl, ethyl, propyl, n-butyl, t-butyl, phenyl, or benzyl.

4. The organotin polymer photoresist composition of claim 1, wherein M=Sn, E=O.

5. The organotin polymer photoresist composition of claim 1, wherein R¹ is a substituted or unsubstituted alkyl, alkenyl group with 1 to 20 carbon atom.

6. The organotin polymer photoresist composition of claim 1, wherein the substituted includes fluorine.

7. The organotin polymer photoresist composition of claim 1, wherein the additive comprises organic thiol, organic alcohol, organic amine, organic amide, organic carboxylic acid, organic phosphine, organic phosphine oxide, or organic phosphonic acid.

8. The organotin polymer photoresist composition of claim 1, wherein the photoresist is for extreme ultraviolet photolithography.

9. An organotin polymer photoresist, having a chemical structure containing stannocenyl group represented by the following: 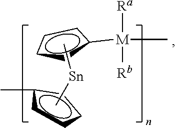
wherein M=C, Si, Ge, Sn, or Pb; R^{a}, R^{b} are each independently —R¹, —ER¹, —N(R¹)₂, or —O—(C═O) R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te.

10. The organotin polymer photoresist of claim 9, wherein stannocenyl is bis(cyclopentadienyl) tin, or substituted bis(cyclopentadienyl) tin, wherein cyclopentadienyl comprises cyclopentadienyl C₅H₅ group, or substituted cyclopentadienyl C₅H₃R, C₅H₂R₂, C₅HR₃, C₅R₄, or C₅R₅ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group.

11. The organotin polymer photoresist of claim 9, wherein the photoresist is an extreme ultraviolet lithography photoresist.

12. The organotin polymer photoresist of claim 9, wherein the organotin polymer is prepared from ansa-bridged [1] stannocenophane represented by a chemical formula from below: 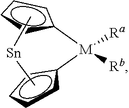
wherein M=C, Si, Ge, Sn, or Pb; R^{a}, R^{b} are each independently —R¹, —ER¹, —N(R¹)₂, or —O—(C═O) R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te.

13. The organotin polymer photoresist of claim 10, wherein R is H, methyl, ethyl, propyl, n-butyl, t-butyl, phenyl, or benzyl.

14. The organotin polymer photoresist of claim 9, wherein M=Sn.

15. The organotin polymer photoresist of claim 9, wherein R^{a}, R^{b} are —OR¹, —N(R¹)₂, or —O—(C═O)R¹ group.

16. The organotin polymer photoresist of claim 9, wherein R¹ is a substituted or unsubstituted alkyl, alkenyl group with 1 to 20 carbon atoms.

17. A method for photolithography patterning, comprising:
depositing an organotin polymer photoresist composition over a substrate; wherein the organotin polymer photoresist composition comprises an organotin polymer, a solvent and an additive;
exposing the organotin photoresist layer to actinic radiation to form a latent pattern; and
developing the latent pattern by applying a developer to remove unexposed or exposed portion of photoresists to form a photolithography pattern.

18. The method for photolithography patterning of claim 17, wherein the organotin polymer having a chemical structure containing cyclopentadienyl group is selected from the following: 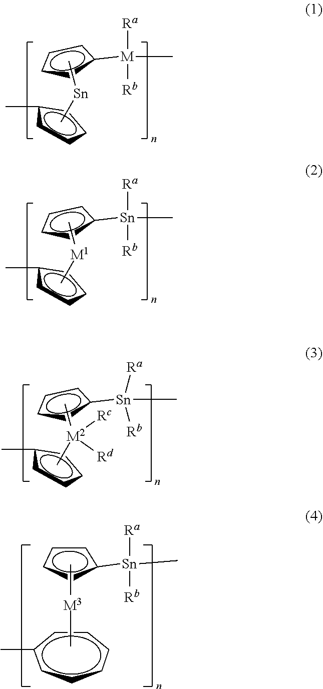
wherein M=C, Si, Ge, Sn, or Pb; M¹=Fe, Ru, Ni, V, Co, Zn, Mg, Cr, Mn, Sb, Bi, or In; M²=Sn, Ti, Zr, or Hf, or Nb; M³=Ti, V, or Cr; R^{a}, R^{b}, R^{c}, R^{d} are each independently —R¹, —ER¹, —N(R¹)₂, or —O—(C═O) R¹, wherein R¹ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te.

19. The method for photolithography patterning of claim 18, wherein cyclopentadienyl group comprises cyclopentadienyl C₅H₄ group, or substituted cyclopentadienyl C₅H₃R, C₅H₂R₂, C₅HR₃, or C₅R₄ group with hapticity of η¹, η², η³, η⁴, or η⁵ of isomers, wherein R is H, a substituted or unsubstituted alkyl, alkenyl, alkynyl, or cycloalkyl group with 1 to 20 carbon atoms, or a substituted or unsubstituted aryl group with 6-20 carbon atoms, or an amino, cyano, ether, ester, halide, nitro, silyl, thiol, or carbonyl group.

20. The method for photolithography patterning of claim 17, wherein actinic radiation includes extreme ultraviolet radiation, deep ultraviolet radiation, e-beam radiation, X-ray radiation, or ion-beam radiation.
